(19) United States
(12) Patent Application Publication
(10) Pub. No.: US 2024/0365627 A1
(43) Pub. Date: Oct. 31, 2024

(54) DISPLAY DEVICE AND METHOD OF MANUFACTURING THE SAME

(71) Applicant: Samsung Display Co., LTD., Yongin-si (KR)

(72) Inventors: JONGSEOK HAN, Yongin-si (KR); DALHO KIM, Yongin-si (KR); HYANGKI SUNG, Yongin-si (KR); EUNJI PARK, Yongin-si (KR); HEESEONG JEONG, Yongin-si (KR)

(21) Appl. No.: 18/423,763

(22) Filed: Jan. 26, 2024

(30) Foreign Application Priority Data
Apr. 25, 2023 (KR) 10-2023-0054156

(51) Int. Cl. H10K 59/35; H10K 59/80; H10K 71/60; H10K 102/00

(52) U.S. Cl. CPC H10K 59/353; H10K 59/873; H10K 71/60; H10K 2102/351

(57) ABSTRACT

A display device includes: a substrate, a pixel electrode disposed on the substrate, a light emitting element layer including a first light emitting layer disposed on the pixel electrode and having a first luminous efficiency and a second light emitting layer disposed on the first light emitting layer and having a second luminous efficiency higher than the first luminous efficiency, and a common electrode disposed on the light emitting element layer.

This application claims priority to Korean Patent Application No. 10-2023-0054156, filed on Apr. 25, 2023, and all the benefits accruing therefrom under 35 U.S.C. § 119, the content of which in its entirety is herein incorporated by reference.

### BACKGROUND

### 1. Technical Field

Embodiments provide generally to a display device. More particularly, embodiments relate to a display device and a method of manufacturing the display device.

### 2. Description of the Related Art

A light emitting display device is a self-emitting display device that displays images using a light emitting diode. Unlike a liquid crystal display, a light emitting display device do not require a separate light source, so the thickness and weight of the light emitting display can be relatively reduced. In addition, the light emitting display device are attracting attention as next-generation display device for portable electronic device because the light emitting display device exhibit high-quality characteristics such as low power consumption, high brightness, and high response speed.

Generally, a light emitting element has a hole injection layer, a light emitting layer, and an electron injection layer. The light emitting element generates light by energy generated when excitons formed by combining holes supplied from the hole injection layer and electrons supplied from the electron injection layer within the light emitting layer fall to a ground state. In the case of the light emitting element, the self-efficiency of the light emitting element is not high, so an internal resonance environment is created to improve efficiency. However, in the internal resonance environment, the path of light from the front is different depending on color of the light, so the efficiency ratios of red, green, and blue are different from each other, resulting in color difference (“WAD” characteristic, WAD) depending on the angle both in the front and the side. In other words, the WAD is an item that evaluates the change in white characteristics depending on the observation angle. In addition, a significant part of the light emitted from the light emitting layer is guided in a direction parallel to the stacking surface and is lost due to total reflection, resulting in low luminous efficiency. “Luminous efficiency” refers to the ratio of the amount of light extracted from the element to the observer with respect to the amount of light emitted from the light emitting layer. In other words, the luminous efficiency is a measure of how well a light source produces visible light. It is the ratio of luminous flux to power, measured in lumens per watt in the International System of Units (ISU) for example. Since the light emitting element has low light extraction efficiency, there is much room for improvement in the characteristics of display devices, such as brightness.

As such, in order to improve the performance of the light emitting display device, various methods are desirable to effectively extract light generated from the light emitting layer to improve luminous efficiency and reduce color difference to improve visibility.

### SUMMARY

Embodiments provide a display device having improved reliability.

Embodiments provide a method of manufacturing the display device.

A display device according to embodiments of the present disclosure includes: a substrate, a pixel electrode disposed on the substrate; a light emitting element layer including a first light emitting layer disposed on the pixel electrode and having a first luminous efficiency and a second light emitting layer disposed on the first light emitting layer and having a second luminous efficiency higher than the first luminous efficiency; and a common electrode disposed on the light emitting element layer.

In an embodiment, the second luminous efficiency may be about three times the first luminous efficiency.

In an embodiment, the second light emitting layer may have a thickness greater than a thickness of the first light emitting layer.

In an embodiment, the thickness of the second light emitting layer may be about 50 angstroms to about 200 angstroms greater than the thickness of the first light emitting layer.

In an embodiment, the light emitting element layer may further include a first electron transport layer disposed between the first light emitting layer and the second light emitting layer, a hole transport layer disposed between the first electron transport layer and the second light emitting layer, and a second electron transport layer disposed between the second light emitting layer and the common electrode.

In an embodiment, the display device may further include an encapsulation layer disposed on the common electrode.

In an embodiment, the encapsulation layer may include a first encapsulation layer including silicon nitride, a second encapsulation layer disposed on the first encapsulation layer and including silicon oxynitride, and a third encapsulation layer disposed on the second encapsulation layer and including silicon oxynitride.

In an embodiment, a refractive index of the first encapsulation layer may be greater than each of a refractive index of the second encapsulation layer and a refractive index of the third encapsulation layer, and the refractive index of the second encapsulation layer may be greater than the refractive index of the third encapsulation layer.

In an embodiment, a thickness of the first encapsulation layer may range from about 1000 angstroms to about 1600 angstroms, a thickness of the second encapsulation layer May range from about 6000 angstroms to about 12000 angstroms, and a thickness of the third encapsulation layer may range from about 50 angstroms to about 100 angstroms.

In an embodiment, the light emitting element layer may further include a charge generating layer disposed between the first light emitting layer and the second light emitting layer.

A method of manufacturing a display device according to embodiments of the present disclosure includes: forming a pixel electrode on a substrate; forming a first light emitting layer having a first luminous efficiency on the pixel electrode; forming a second light emitting layer having a second luminous efficiency higher than the first luminous efficiency on the first light emitting layer; and forming a common electrode on the second light emitting layer.

In an embodiment, the first light emitting layer and the second light emitting layer may form a light emitting element layer.

In an embodiment, a luminous efficiency of the light emitting element layer may be adjusted by adjusting a thickness of the second light emitting layer with respect to a thickness of the first light emitting layer.

In an embodiment, the thickness of the second light emitting layer may be greater than the thickness of the first light emitting layer.

In an embodiment, the thickness of the second light emitting layer may be about 50 angstroms to about 200 angstroms greater than the thickness of the first light emitting layer.

In an embodiment, the method may further include: forming a hole injection layer on the pixel electrode before the forming of the first light emitting layer; forming a hole transport layer on the first light emitting layer; and forming an electron transport layer on the second light emitting layer after the forming of the second light emitting layer.

In an embodiment, a luminous efficiency of the light emitting element layer may be adjusted by adjusting a thickness of each of the hoe injection layer, the hole transport layer, and the electron transport layer.

In an embodiment, the method may further include: forming a first encapsulation layer including silicon nitride on the common electrode, forming a second encapsulation layer including silicon oxynitride on the first encapsulation layer, and forming a third encapsulation layer including silicon oxynitride on the second encapsulation layer.

In an embodiment, a refractive index of each of the first, second, and third encapsulation layers may be adjusted by adjusting a content ratio of elements included in each of the first, second, and third encapsulation layers.

In an embodiment, a luminous efficiency of the light emitting element layer may be adjusted by adjusting a thickness of each of the first, second, and third encapsulation layers.

In a display device according to embodiments of the present disclosure, the display device may include a first light emitting layer having a first light emitting efficiency and a second light emitting layer having a second luminous efficiency, and the first light emitting efficiency may be greater than the second light emitting efficiency. As a result, the luminous efficiency and luminance ratio of the display device can be improved. In addition, the white angle difference (WAD) margin of the display device can be increased. Accordingly, when the WAD margin is increased, the same WAD characteristics can be obtained even when the dispersion of the film thickness is increased. Accordingly, the reliability of the display device can be effectively improved.

### BRIEF DESCRIPTION OF THE DRAWINGS

Illustrative, non-limiting embodiments will be more clearly understood from the following detailed description in conjunction with the accompanying drawings.

FIG. 1 is a plan view of a display device according to an embodiment of the present disclosure.

FIG. 2 is an enlarged plan view of area A of FIG. 1.

FIG. 3 is a cross-sectional view taken along line I-I′ of FIG. 2.

FIG. 4 is an enlarged cross-sectional view illustrating a pixel electrode, a light emitting element layer, a common electrode, and an encapsulation layer for each pixel in FIG. 3.

FIG. 5 is graphs illustrating WAD characteristics in Examples and Comparative Examples.

FIG. 6 is graphs illustrating WAD margin movement (movement amount) in Examples and Comparative Examples.

FIGS. 7, 8, 9, 10, 11, 12, and 13 are views illustrating a method of manufacturing a display device according to an embodiment of the present disclosure.

FIG. 14 is graphs illustrating WAD characteristics in Comparative Example and Examples.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Hereinafter, embodiments of the present disclosure will be explained in detail with reference to the accompanying drawings. The same reference numerals are used for the same components in the drawings, and redundant descriptions of the same components will be omitted.

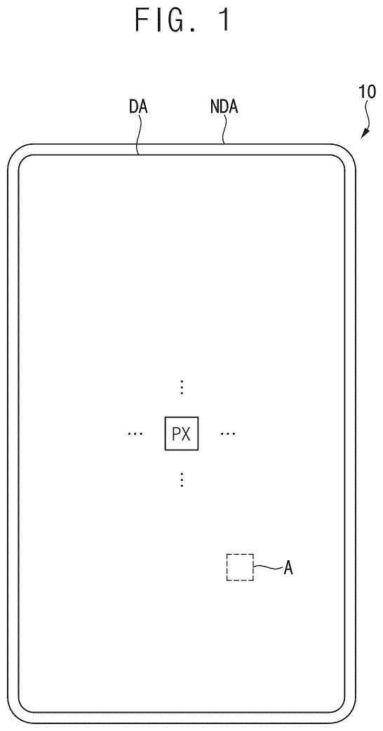

FIG. 1 is a plan view of a display device according to an embodiment of the present disclosure.

Referring to FIG. 1, a display device 10 may include a display area DA and a non-display area NDA. The display area DA may be an area that displays an image. The planar shape of the display area DA may be a rectangular shape or, as shown in FIG. 1, a rectangular shape with rounded corners. However, the planar shape of the display area DA is not limited to this, and the display area DA may have various planar shapes such as circular, oval, polygonal shapes, or the like.

The non-display area NDA may be arranged around the display area DA. The non-display area NDA may surround the display area DA. The non-display area NDA may be an area that does not display images. In one embodiment, drivers for displaying images in the display area DA may be disposed in the non-display area NDA.

Pixels PX may be arranged in a matrix in the display area DA. Signal lines such as gate lines and data lines may be disposed in the display area DA. The signal lines, such as the gate line and the data line, may be connected to each of the pixels PX. Each of the pixels PX may receive a gate signal, a data signal, and the like from the signal line.

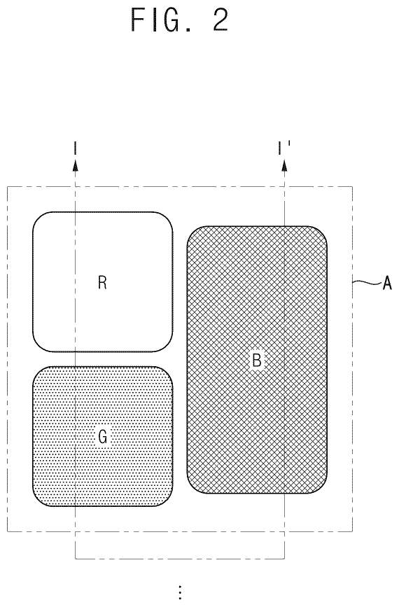

FIG. 2 is an enlarged plan view of area A of FIG. 1.

Referring to FIG. 2, the display device 10 according to an embodiment of the present disclosure may include a red pixel R that displays red, a green pixel G that displays green, and a blue pixel B that displays blue. There is. The red pixel R, the green pixel G, and the blue pixel B may be basic pixels for expressing full color.

The red pixel R, the green pixel G, and the blue pixel B may form one group and may be repeatedly arranged in an n×m matrix. In an embodiment, for example, a plurality of red pixels R and a plurality of green pixels G may be arranged alternately along a first column, and a plurality of blue pixels B may be arranged continuously along a second column adjacent to the first column.

The red pixel R and the green pixel G may have substantially the same area. The blue pixel B may have a larger area than the red pixel R and the green pixel G. By forming the blue pixel B with a larger area than the red pixel R and the green pixel G, the luminance of the red pixel R, the green pixel G, and the blue pixel B may be balanced. However, the present disclosure is not limited to this, and the shape of the pixels and the arrangement of the pixels may be modified in various ways, and may further include white pixels that display white color.

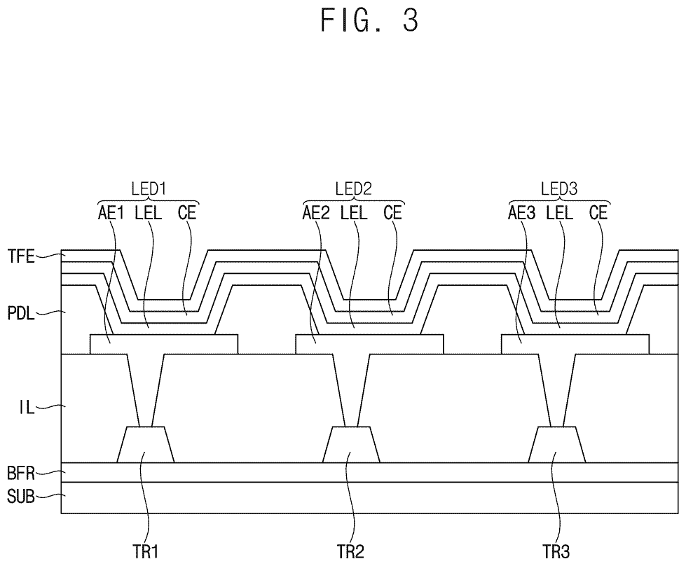

FIG. 3 is a cross-sectional view taken along line I-I′ of FIG. 2.

FIGS. 1, 2, and 3, the display device 10 may include a substrate SUB, a buffer layer BFR, first, second, and third driving elements TR1, TR2, and TR3, an insulating layer IL, a pixel definition layer PDL, first, second, and third light emitting elements LED1, LED2, and LED3, and an encapsulation layer TFE.

The substrate SUB may be an insulating substrate made of a transparent or opaque material. In an embodiment, the substrate SUB may include glass. In another embodiment, the substrate SUB may include plastic.

The buffer layer BFR may be disposed on the substrate SUB. The buffer layer BFR can prevent impurities such as oxygen and moisture from diffusing into an upper part of the substrate SUB. The buffer layer BFR may include an inorganic material such as a silicon compound, metal oxide, or the like. The buffer layer BFR may have a single-layer structure or a multi-layer structure including a plurality of insulating layers.

The first, second, and third driving elements TR1, TR2, and TR3 may be disposed on the buffer layer BFR. Each of the first, second, and third driving elements TR1, TR2, and TR3 may include at least one thin film transistor. The channel layer of the thin film transistor may include an oxide semiconductor, a silicon semiconductor, an organic semiconductor, or the like. In an embodiment, for example, the oxide semiconductor may include at least one oxide from indium (In), gallium (Ga), tin (Sn), zirconium (Zr), vanadium (V), hafnium (Hf), cadmium (Cd), germanium (Ge), chromium (Cr), titanium (Ti), zinc (Zn), and the like. The silicon semiconductor may include amorphous silicon, polycrystalline silicon, and/or the like.

The insulating layer IL may cover the first, second, and third driving elements TR1, TR2, and TR3. The insulating layer IL may include a combination of an inorganic insulating layer and an organic insulating layer.

The first, second, and third light emitting elements LED1, LED2, and LED3 may be disposed on the insulating layer IL. For example, first, second, and third pixel electrodes AE1, AE2, and AE3 may be disposed on the insulating layer IL. Each of the first, second, and third pixel electrodes AE1, AE2, and AE3 may include a conductive material such as a metal, alloy, conductive metal nitride, conductive metal oxide, transparent conductive material, and the like. Each of the first, second, and third pixel electrodes AE1, AE2, and AE3 may have a single-layer structure or a multi-layer structure including a plurality of conductive layers.

The first, second, and third pixel electrodes AE1, AE2, and AE3 may be electrically connected to the first, second, and third driving elements TR1, TR2, and TR3, respectively, through contact holes formed in the insulating layer IL.

The pixel defining layer PDL may be disposed on the first, second, and third pixel electrodes AE1, AE2, and AE3. The pixel defining layer PDL may include an organic material. The pixel defining layer PDL may define a pixel opening exposing at least a part of each of the first, second, and third pixel electrodes AE1, AE2, and AE3.

A light emitting element layer LEL may be disposed on the first, second, and third pixel electrodes AE1, AE2, and AE3 exposed by the pixel opening of the pixel defining layer PDL. In an embodiment, the light emitting element layer LEL may extend continuously on the display area DA across a plurality of pixels. In another embodiment, the light emitting element layer LEL may be separated from the light emitting layer of an adjacent pixel.

A common electrode CE may be disposed on the light emitting element layer LEL. The common electrode CE may include a conductive material such as a metal, alloy, conductive metal nitride, conductive metal oxide, transparent conductive material, and the like. The common electrode CE may have a single-layer structure or a multi-layer structure including a plurality of conductive layers. In an embodiment, the common electrode CE may extend continuously on the display area DA across a plurality of pixels.

The first pixel electrode AE1, the light emitting element layer LEL, and the common electrode CE may form the first light emitting element LED1, the second pixel electrode AE2, the light emitting element layer LEL, and the common electrode CE may form the second light emitting element LED2, and the third pixel electrode AE3, the light emitting element layer LEL, and the common electrode CE may form the third light emitting element LED3.

The encapsulation layer TFE may be disposed on the common electrode CE. In an embodiment, the encapsulation layer TFE may have a multi-layer structure.

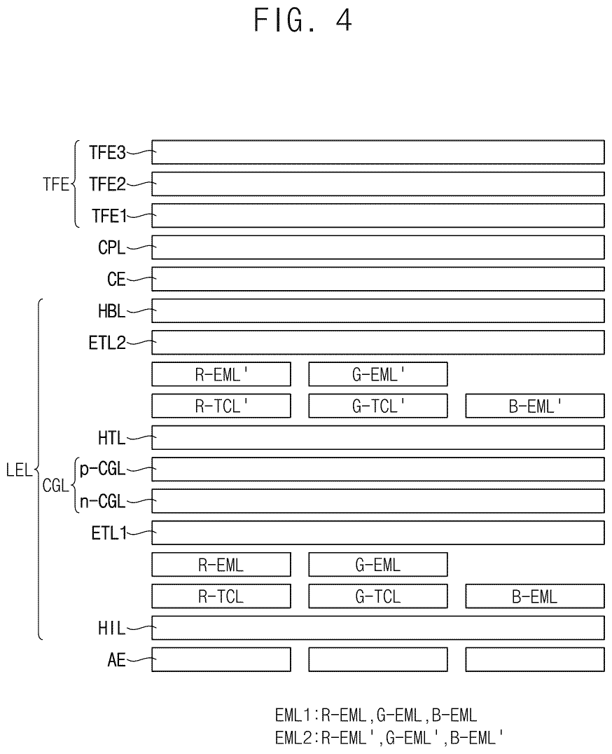

FIG. 4 is an enlarged cross-sectional view illustrating a pixel electrode, a light emitting element layer, a common electrode, and an encapsulation layer for each pixel in FIG. 3.

Referring to FIGS. 1, 2, 3, and 4, the light emitting element layer LEL may be disposed between the pixel electrode AE and the common electrode CE. The light emitting element layer LEL may include a hole injection layer HIL, a first light emitting layer EML1, a first red thickness compensation layer R-TCL, a first green thickness compensation layer G-TCL, a first electron transport layer ETL1, a charge generation layer CGL, a hole transport layer HTL, a second light emitting layer EML2, a second red thickness compensation layer R-TCL′, a second green thickness compensation layer G-TCL′, a second electron transport layer ETL2, and a hole blocking layer HBL.

The hole injection layer HIL may be disposed on the pixel electrode AE. The hole injection layer HIL can control the energy level of the interface to facilitate charge generation and movement to the first light emitting layer EML1.

The first light emitting layer EML1 may be disposed on the hole injection layer HIL. The first light emitting layer EML1 may include a red light emitting layer R-EML overlapping the red pixel R, a green light emitting layer B-EML overlapping the green pixel G, and a blue light emitting layer B-EML overlapping the blue pixel B in a plan view.

The first light emitting layer EML1 may include at least one of an organic light-emitting material and quantum dots. The red light emitting layer R-EML may generate red light. The green light emitting layer G-EML may generate green light. The blue light emitting layer B-EML may generate blue light. However, the present disclosure is not limited to this.

The first red thickness compensation layer R-TCL may overlap the red light emitting layer R-EML and may be disposed under the red light emitting layer R-EML. The first green thickness compensation layer G-TCL may overlap the green light emitting layer G-EML and may be disposed under the green light emitting layer G-EML in a plan view. The first red thickness compensation layer R-TCL and the first green thickness compensation layer G-TCL may control resonance while serving as an electron blocking layer. That is, in the case of the red pixel R, since red has a long wavelength, the stack thickness may be formed to be thick. Accordingly, the first red thickness compensation layer R-TCL may be formed to compensate for the stacked thickness of the red pixel R. In addition, in the case of the green pixel G, since green has a shorter wavelength than red, the stack thickness may be formed relatively thin. Accordingly, the first green thickness compensation layer G-TCL may be formed to compensate for the stacked thickness of the green pixel G. Lastly, in the case of the blue pixel B, since blue has the shortest wavelength, the stack thickness may be formed to be thin. Accordingly, the blue pixel B may not require a thickness compensation layer to compensate for the stack thickness.

The first electron transport layer ETL1 may be disposed on the first light emitting layer EML1. The first electron transport layer ETL1 may transfer electrons to the first light emitting layer EML1.

The charge generation layer CGL may be disposed on the first electron transport layer ETL1. The charge generation layer CGL may increase the mobility of electrons toward the first light emitting layer EML1 and the mobility of holes toward the second light emitting layer EML2. The charge generation layer CGL may include an n-type charge generation layer n-CGL and a p-type charge generation layer p-CGL. The n-type charge generation layer n-CGL may be disposed on the first electron transport layer ETL1, and the p-type charge generation layer p-CGL may be disposed on the n-type charge generation layer n-CGL.

The hole transport layer HTL may be disposed on the charge generation layer CGL. The hole transport layer HTL may transfer holes to the second light emitting layer EML2.

The second light emitting layer EML2 may be disposed on the hole transport layer HTL. The second light emitting layer EML2 may have the same structure as the first light emitting layer EML1. That is, the second light emitting layer EML2 may include a red light emitting layer R-EML′ overlapping the red pixel R, a green light emitting layer G-EML′ overlapping the green pixel G, and a blue light emitting layer B-EML′ overlapping the blue pixel B in a plan view.

In addition, the second red thickness compensation layer R-TCL′ may overlap the red light emitting layer R-EML′ and may be disposed under the red light emitting layer R-EML′. The second green thickness compensation layer G-TCL′ may overlap the green light emitting layer G-EML′ and may be disposed under the green light emitting layer G-EML′. The second red thickness compensation layer R-TCL′ and the second green thickness compensation layer G-TCL′ may control resonance while serving as an electron blocking layer. That is, in the case of the red pixel R, since red has a long wavelength, the stack thickness may be formed to be thick. Accordingly, the second red thickness compensation layer R-TCL′ may be formed to compensate for the stacked thickness of the red pixel R. In addition, in the case of the green pixel G, since green has a shorter wavelength than red, the stack thickness may be formed relatively thin. Accordingly, the second green thickness compensation layer G-TCL′ may be formed to compensate for the stacked thickness of the green pixel G.

The second electron transport layer ETL2 may be disposed on the second light emitting layer EML2. The second electron transport layer ETL2 may transfer electrons to the second light emitting layer EML2.

The hole blocking layer HBL may be disposed on the second electron transport layer ETL2. The hole blocking layer HBL may serve to prevent hole injection.

The common electrode CE may be disposed on the hole blocking layer HBL.

A capping layer CPL may be disposed on the common electrode CE. The capping layer CPL may be formed in a multi-layer structure. However, the present disclosure is not limited to this.

The encapsulation layer TFE may be formed on the capping layer CPL. The encapsulation layer TFE may include a first encapsulation layer TFE1, a second encapsulation layer TFE2, and a third encapsulation layer TFE3. The first encapsulation layer TFE1 may be disposed on the common electrode CE. The first encapsulation layer TFE1 may include silicon nitride. The second encapsulation layer TFE2 may be disposed on the first encapsulation layer TFE1. The second encapsulation layer TFE2 may include silicon oxynitride. The third encapsulation layer TFE3 may be disposed on the second encapsulation layer TFE2. The third encapsulation layer TFE3 may include silicon oxynitride.

In an embodiment, the first light emitting layer EML1 may have a first luminous efficiency. The second light emitting layer EML2 may have a second luminous efficiency. The luminous efficiency of the light emitting element layer LEL may be adjusted by adjusting the first luminous efficiency and the second luminous efficiency. That is, the first luminous efficiency and the second luminous efficiency may be different from each other. In an embodiment, the second luminous efficiency may be higher than the first luminous efficiency. In an embodiment, for example, the second luminous efficiency may be about three times the first luminous efficiency.

In an embodiment, the first luminous efficiency and the second luminous efficiency may be adjusted by adjusting the thicknesses of the first and second light emitting layers EML1 and EML2, respectively. That is, as the thickness of the light emitting layer increases, the luminous efficiency of the light emitting layer may increase. Accordingly, the thickness of the second emitting layer EML2 may be greater than the thickness of the first emitting layer EML1. In an embodiment, for example, the thickness of the second emitting layer EML2 may be about 50 angstroms to about 200 angstroms greater than the thickness of the first emitting layer EML1.

When the difference between the thicknesses of the second light emitting layer EML2 and the first light emitting layer EML1 is about 50 angstroms or less, there may be no substantial difference between the second luminous efficiency and the first luminous efficiency. Accordingly, since the first luminous efficiency and the second luminous efficiency are substantially the same, the luminous efficiency of the light emitting element layer LEL may not be improved. In addition, when the difference between the thicknesses of the second light emitting layer EML2 and the first light emitting layer EML1 is about 200 angstroms or more, the driving voltage of the light emitting element layer LEL may increase. In addition, even when the difference between the thicknesses of the second light emitting layer EML2 and the first light emitting layer EML1 is about 200 angstroms or more, there may be no substantial difference between the second luminous efficiency and the first luminous efficiency.

In an embodiment, the luminous efficiency of the light emitting element layer LEL may be adjusted by adjusting the thickness of each of the hole injection layer HIL, the hole transport layer HTL, and the second electron transport layer ETL2. When the thickness of each of the hole injection layer HIL, the hole transport layer HTL, and the second electron transport layer ETL2 is changed in a range between about 100 angstroms and about 500 angstroms, each of the first luminous efficiency and the second luminous efficiencies may be changed. In an embodiment, for example, when the thickness of the hole injection layer HIL is changed, the first luminous efficiency may be changed, and when the thicknesses of each of the hole transport layer HTL and the second electron transport layer ETL2 is changed, the second luminous efficiency may be changed.

In an embodiment, the luminous efficiency of the light emitting element layer LEL may be adjusted by changing the materials of each of the hole blocking layer HBL, the hole transport layer HTL, and the hole injection layer HIL.

In an embodiment, the luminous efficiency of the light emitting element layer LEL may be adjusted by adjusting the refractive index of each of the first, second, and third encapsulation layers TFE1, TFE2, and TFE3. That is, the refractive index of each of the first, second, and third encapsulation layers TFE1, TFE2, TFE3 may be adjusted by adjusting the content ratio of elements contained in each of the first, second, and third encapsulation layers TFE1, TFE2, and TFE3. In an embodiment, for example, the refractive index of the first encapsulation layer TFE1 may be adjusted by adjusting the content ratio of silicon and nitrogen in the silicon nitride included in the first encapsulation layer TFE1. The refractive index of the second encapsulation layer TFE2 may be adjusted by adjusting the content ratio of oxygen and nitrogen in the silicon oxynitride included in the second encapsulation layer TFE2. In addition, the refractive index of the third encapsulation layer TFE3 may be adjusted by adjusting the content ratio of oxygen and nitrogen in the silicon oxynitride included in the third encapsulation layer TFE3.

In an embodiment, the refractive index of the first encapsulation layer TFE1 may be greater than each of the refractive index of the second encapsulation layer TFE2 and the refractive index of the third encapsulation layer TFE3. In addition, the refractive index of the second encapsulation layer TFE2 may be greater than the refractive index of the third encapsulation layer TFE3. In an embodiment, for example, the refractive index of the first encapsulation layer TFE1 may be about 1.89, the refractive index of the second encapsulation layer TFE2 may be about 1.62, and the refractive index of the third encapsulation layer TFE3 may be about 1.57. However, the present disclosure is not limited to this.

In an embodiment, the luminous efficiency of the light emitting element layer LEL may be adjusted by adjusting the thickness of each of the first, second, and third encapsulation layers TFE1, TFE2, and TFE3. In an embodiment, for example, the thickness of the first encapsulation layer TFE1 may range from about 1000 angstroms to about 1600 angstroms. The thickness of the second encapsulation layer TFE2 may range from about 6000 angstroms to about 12000 angstroms. The thickness of the third encapsulation layer TFE3 may range from about 50 angstroms to about 100 angstroms. However, the present disclosure is not limited to this.

In an embodiment, since the second luminous efficiency is greater than the first luminous efficiency, the luminous efficiency and luminance ratio of the display device 10 can be improved. In addition, the white angle difference (WAD) margin of the display device 10 can be increased. WAD is an item that evaluates the change in white characteristics depending on the observation angle. In an embodiment, for example, WAD characteristics may be evaluated by measuring the amount of change in luminance and change in color coordinates according to the observation angle compared to the front view observed in a direction perpendicular to the screen. Accordingly, when the WAD margin is increased, the same WAD characteristics can be obtained even when the dispersion of the film thickness is increased. Accordingly, the reliability of the display device 10 can be effectively improved.

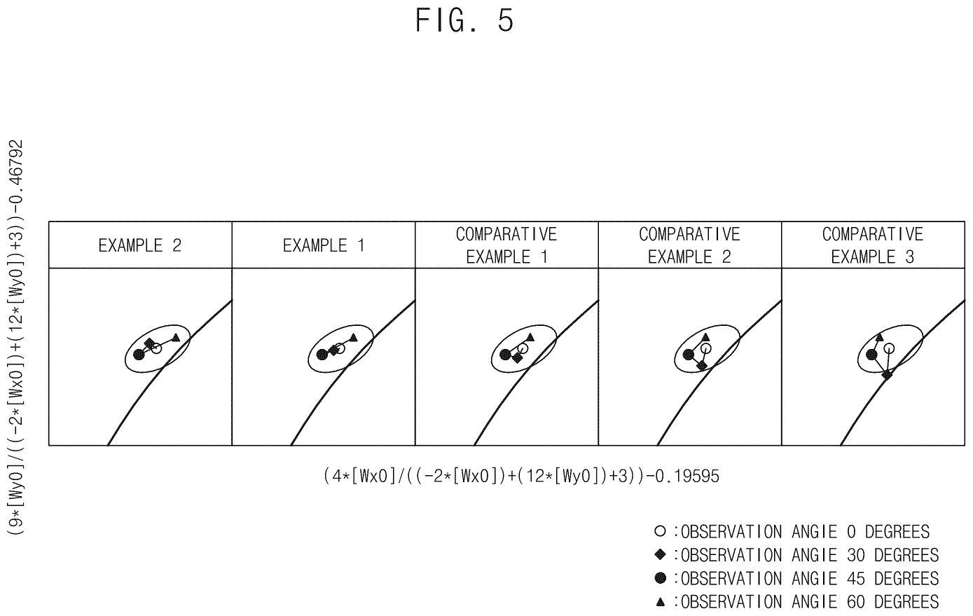

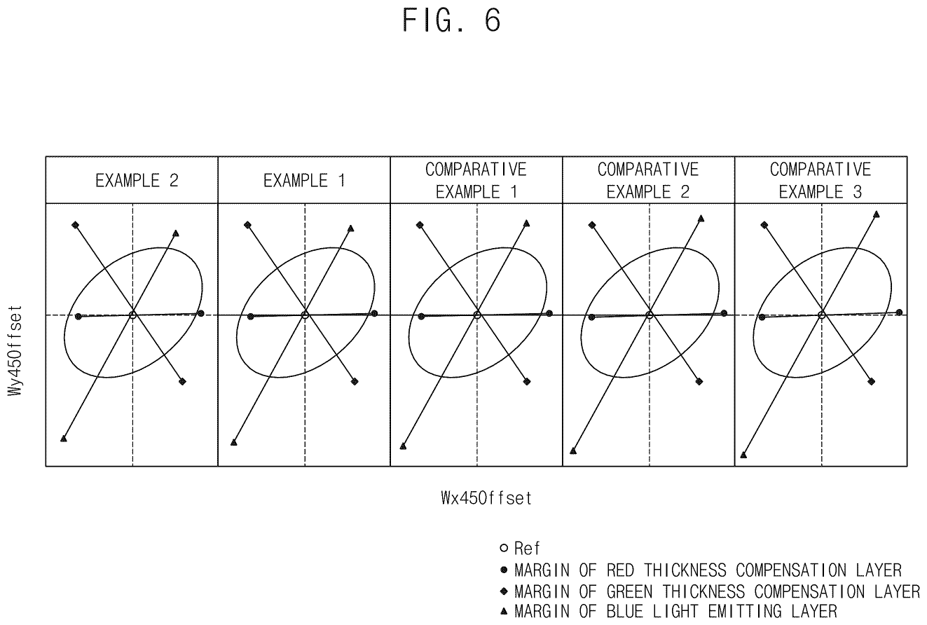

Hereinafter, the effects of the present disclosure will be further described with further reference to Table 1, Table 2, FIG. 5, and FIG. 6.

### Example 1, Example 2, Comparative Example 1, Comparative Example 2, and Comparative Example 3

Under the condition that the sum of the first luminous efficiency and the second luminous efficiency of the light emitting element layers according to each of Example 1, Example 2, Comparative Example 1, Comparative Example 2, and Comparative Example 3 is 2, the first luminous efficiency and the second luminous efficiency according to each of Example 1, Example 2, Comparative Example 1, Comparative Example 2, and Comparative Example 3 are shown in Table 1 below:

TABLE 1

| | | | Comparative | Comparative | Comparative |
|---|---|---|---|---|---|
| | Example 2 | Example 1 | Example 1 | Example 2 | Example 3 |
| First luminous efficiency | 0.5 | 0.75 | 1 | 1.25 | 1.5 |
| Second luminous efficiency | 1.5 | 1.25 | 1 | 0.75 | 0.5 |

The characteristics of the light emitting element layer according to comparative examples and examples are shown in Table 2 below:

TABLE 2

| | White efficiency | | Hole | Red thickness | Green thickness |
|---|---|---|---|---|---|
| | increase ratio | Luminance | transport | compensation | compensation |
| | (Δ Weff) | ratio | layer margin | layer margin | layer margin |
| Example 2 | 2.6% | 0.45 | 21.1% | 4.3% | −0.4% |
| Example 1 | 1.3% | 0.42 | 11.8% | 2.5% | 0.0% |
| Comparative Example 1 | 0.0% | 0.39 | 0.0% | 0.0% | 0.0% |
| Comparative Example 2 | −1.4% | 0.36 | −12.4% | −2.8% | 0.0% |
| Comparative Example 3 | −3.0% | 0.33 | −24.1% | −6.4% | −0.7% |

FIG. 5 is graphs illustrating WAD characteristics in Examples and Comparative Examples. FIG. 6 is graphs illustrating WAD margin movement (movement amount) in Examples and Comparative Examples.

In FIG. 5, Wx0 means an initial color coordinate of the x-axis, and Wy0 means an initial color coordinate of the y-axis. In addition, in FIG. 6, Wx45Offset means the x-axis color coordinate offset after 45 hours of driving time, and Wy45Offset means the y-axis color coordinate offset after 45 hours of driving time.

Referring to Table 1, Table 2, FIG. 5, and FIG. 6, under the above conditions, in the Examples and Comparative Examples, WAD characteristics, white efficiency increase ratio, luminance ratio, hole injection layer margin, red thickness compensation layer margin, and green thickness compensation layer margin were measured.

Referring to Tables 1 and 2, here, the “white efficiency” refers to power efficiency when the red pixel (e.g., the red pixel R in FIG. 2), the green pixel (e.g., the green pixel G in FIG. 2), and the blue pixel (e.g., the blue pixel B in FIG. 2) are all turned on and white is displayed. That is, as the white efficiency increases, the luminous efficiency of the light emitting element layer improves. The “white efficiency increase ratio” refers to the ratio of how much the white efficiency of the Examples and Comparative Examples increases or decreases compared to Comparative Example 1.

That the white efficiency increase ratio of the light emitting element layer according to each of Examples 1 and 2 has a positive value can be confirmed. On the other hand, that the white efficiency increase ratio of the light emitting element layer according to each of Comparative Examples 2 and 3 has a negative value can be confirmed. Therefore, that the luminous efficiency of the light emitting element layer according to the Examples is higher than the luminous efficiency of the light emitting device layer according to the Comparative examples can be confirmed.

In addition, that the luminance ratio of the light emitting element layer according to each of Examples 1 and 2 is greater than the luminance ratio of the light emitting element layer according to each of the Comparative Examples can be confirmed.

In addition, that the characteristics of the light emitting element layer according to Example 2 among the examples are excellent can be confirmed. That is, when the second luminous efficiency of the second light emitting layer included in the light emitting element layer is about three times the first luminous efficiency of the first light emitting layer, the characteristics of the light emitting element layer can be excellent.

Referring to Table 1, Table 2, and FIG. 5, that the WAD trajectories according to the Examples are located within the WAD specifications, and the WAD trajectories according to the Comparative Examples are located at or deviate from the edge of the WAD specifications can be confirmed. In addition, that the movement amount of the WAD trajectories according to the Examples is less than the movement amount of the WAD trajectories according to the Comparative Examples can be confirmed.

Referring to Table 1, Table 2, and FIG. 6, the margin in the hole injection layer according to Example 2 was improved by about 21.1% compared to the margin in the hole injection layer according to Comparative Example 1, and the margin in the hole injection layer according to Example 1 was improved by about 11.8% compared to the margin in the hole injection layer according to Comparative Example 1. However, that since the hole injection layer margin according to each of Comparative Examples 2 and 3 have a negative value, the hole injection layer margin according to Comparative Examples 2 and 3 are lower than the hole injection layer margin according to Comparative Example 1 can be confirmed. Similarly, that the red thickness compensation layer margin according to Examples has a positive value, while the red thickness compensation layer margin according to Comparative Examples has a 0 or negative value can be confirmed. Accordingly, that the margin in the red thickness compensation layer according to Examples is improved compared to Comparative Example 1, and the margin in the red thickness compensation layer according to Comparative Examples 2 and 3 is lower compared to in Comparative Example 1 can be confirmed.

Accordingly, that the luminous efficiency, luminance ratio, and WAD characteristics of the light emitting element layer according to Examples in which the second luminous efficiency is higher than the first luminous efficiency are improved compared to the luminous efficiency, luminance ratio, and WAD characteristics of the light emitting element layer according to Comparative Examples in which the second luminous efficiency is equal to or lower than the first luminous efficiency can be confirmed. That is, that the reliability of the light emitting element layer according to Examples is improved compared to the reliability of the light emitting element layer according to Comparative Examples can be confirmed

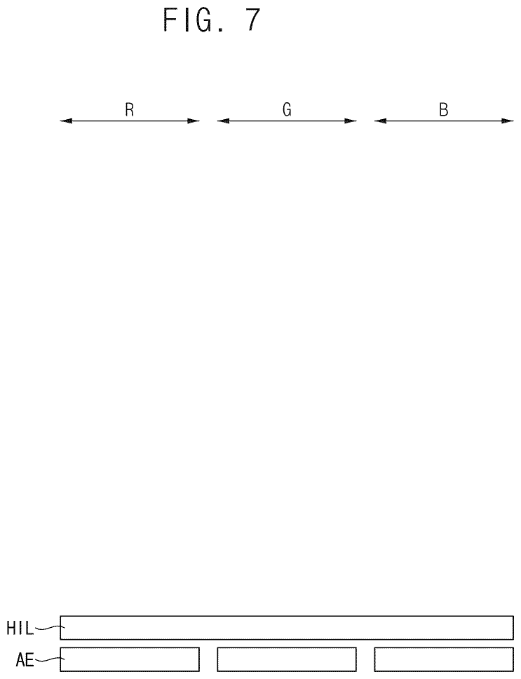

FIGS. 7, 8, 9, 10, 11, 12, and 13 are views illustrating a method of manufacturing a display device according to an embodiment of the present disclosure.

The method of manufacturing the display device described with reference to FIGS. 7, 8, 9, 10, 11, 12, and 13 may be the method of manufacturing the display device 10 described with reference to FIGS. 1, 2, 3, and 4. Accordingly, overlapping descriptions may be simplified or omitted.

Referring to FIG. 7, the pixel electrode AE may be formed on the substrate. The hole injection layer HIL may be formed on the pixel electrode AE. In an embodiment, the first light luminous efficiency of the first light emitting layer, which will be described later, may be adjusted by adjusting the thickness of the hole injection layer HIL. In addition, the first light luminous efficiency of the first light emitting layer may be adjusted by changing the material constituting the hole injection layer HIL.

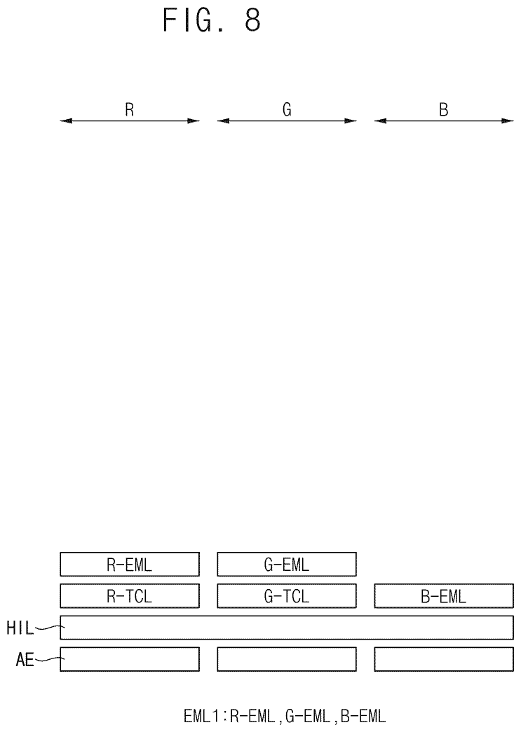

Referring to FIG. 8, in one embodiment, the first red thickness compensation layer R-TCL overlapping the red pixel R and the first green thickness compensation layer G-TCL overlapping the green pixel G in a plan view may be formed on the hole injection layer HIL

In addition, the first light emitting layer EML1 may be formed on the hole injection layer HIL, the first red thickness compensation layer R-TCL, and the first green thickness compensation layer G-TCL. Specifically, the first light emitting layer EML1 may include the red light emitting layer R-EML overlapping the red pixel R, the green light emitting layer G-EML overlapping the green pixel G, and the blue light emitting layer B-EML overlapping the blue pixel B in a plan view. Specifically, the red light emitting layer R-EML may be formed on the first red thickness compensation layer R-TCL, the green light emitting layer G-EML may be formed on the first green thickness compensation layer G-TCL, and the blue light emitting layer B-EML may be formed on the hole injection layer HIL.

In an embodiment, the first light emitting layer EML1 may have the first light luminous efficiency. That is, when the first light emitting layer EML1 is formed, the first light luminous efficiency may be measured. The first luminous efficiency may vary depending on the thickness of the first light emitting layer EML1. As the thickness of the first light emitting layer EML1 increases, the first luminous efficiency may increase. Accordingly, the first light luminous efficiency may be adjusted by adjusting the thickness of the first light emitting layer EML1.

Specifically, the first luminous efficiency of the first light emitting layer EML1 may vary depending on the thickness of each of the red light emitting layer R-EML, the green light emitting layer G-EML, and the blue light emitting layer B-EML included in the first light emitting layer EML1. As the thickness of each of the red light emitting layer R-EML, the green light emitting layer G-EML, and the blue light emitting layer B-EML included in the first light emitting layer EML1 increases, the first luminous efficiency may increase.

In addition, the first luminous efficiency of the first light emitting layer EML1 may be adjusted by adjusting the thickness of each of the first red thickness compensation layer R-TCL and the first green thickness compensation layer G-TCL.

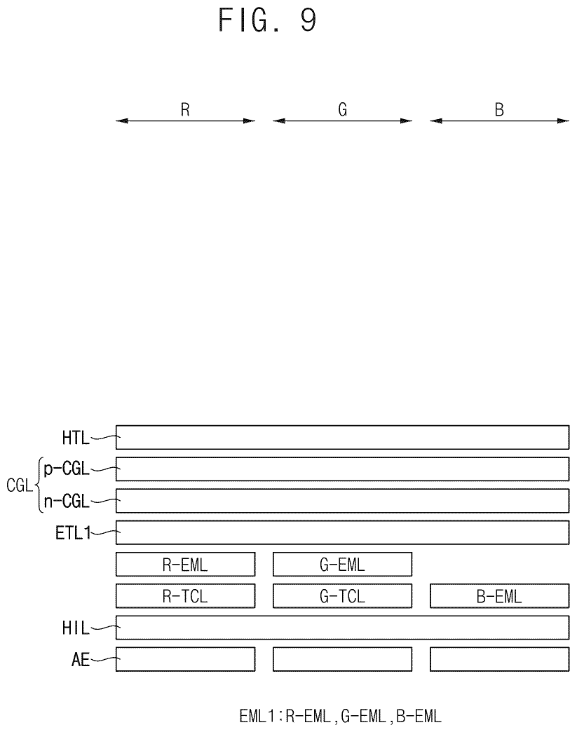

Referring further to FIG. 9, the first electron transport layer ETL1 may be formed on the first light emitting layer EML1. The charge generation layer CGL may be formed on the first electron transport layer ETL1. The charge generation layer CGL may include the n-type charge generation layer n-CGL and the p-type charge generation layer p-CGL. Specifically, the n-type charge generation layer n-CGL may be formed on the first electron transport layer ETL1, and the p-type charge generation layer p-CGL may be formed on the n-type charge generation layer n-CGL.

In addition, the hole transport layer HTL may be formed on the charge generation layer CGL. In an embodiment, the second luminous efficiency of the second light emitting layer EML2, which will be described later, may be adjusted by adjusting the thickness of the hole transport layer HTL. In addition, the second luminous efficiency of the second light emitting layer EML2 may be adjusted by changing the material constituting the hole transport layer HTL.

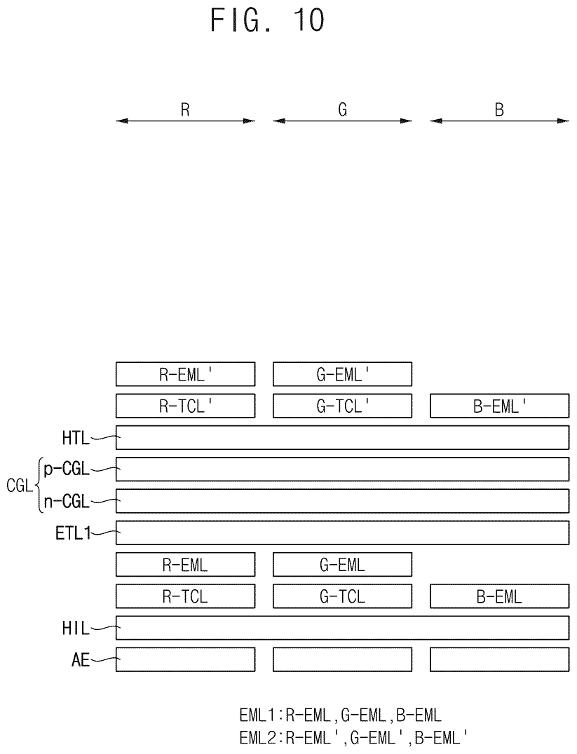

Referring further to FIG. 10, the second red thickness compensation layer R-TCL′ overlapping the red pixel R and the second green thickness compensation layer G-TCL′ overlapping the green pixel G may be formed on the hole transport layer HTL in a plan view.

In addition, the second light emitting layer EML2 may be formed on the hole transport layer HTL, the second red thickness compensation layer R-TCL′, and the second green thickness compensation layer G-TCL′. Specifically, the second light emitting layer EML2 may include the red light emitting layer R-EML′ overlapping the red pixel R, the green light emitting layer G-EML′ overlapping the green pixel G, and the blue light emitting layer B-EML′ overlapping the blue pixel B in a plan view. Specifically, the red light emitting layer R-EML′ may be formed on the second red thickness compensation layer R-TCL′, the green light emitting layer G-EML′ may be formed on the second green thickness compensation layer G-TCL′, and the blue light emitting layer B-EML′ may be formed on the hole transport layer HTL.

In an embodiment, the second light emitting layer EML2 may have the second luminous efficiency. That is, when the second light emitting layer EML2 is formed, the second luminous efficiency may be measured. The second luminous efficiency may vary depending on the thickness of the second light emitting layer EML2. As the thickness of the second light emitting layer EML2 increases, the second luminous efficiency may increase. Accordingly, the second luminous efficiency may be adjusted by adjusting the thickness of the second light emitting layer EML2.

Specifically, the second luminous efficiency of the second light emitting layer EML2 may vary depending on the thickness of each of the red light emitting layer R-EML′, the green light emitting layer G-EML′, and the blue light emitting layer B-EML′ included in the second light emitting layer EML2. As the thickness of each of the red light emitting layer R-EML′, the green light emitting layer G-EML′, and the blue light emitting layer B-EML′ included in the second light emitting layer EML2 increases, the second luminous efficiency may increase.

In addition, the second luminous efficiency of the second light emitting layer EML2 may be adjusted by adjusting the thickness of each of the second red thickness compensation layer R-TCL′ and the second green thickness compensation layer G-TCL′.

In an embodiment, the second luminous efficiency may be higher than the first luminous efficiency. That is, the thickness of the first light emitting layer EML1 and the thickness of the second light emitting layer EML2 may be adjusted so that the second light luminous efficiency is higher than the first luminous efficiency. Therefore, when forming the second light emitting layer EML2, the thickness of the second light emitting layer EML2 may be adjusted based on the thickness of the first light emitting layer EML1. At this time, the thickness of each of the red light emitting layer R-EML′, the green light emitting layer G-EML′, and the blue light emitting layer B-EML′ included in the second light emitting layer EML2 may be adjusted. In addition, the thickness of each of the second red thickness compensation layer R-TCL′ and the second green thickness compensation layer G-TCL′ adjacent to the second light emitting layer EML2 may be adjusted. By adjusting the ratio of the second luminous efficiency of the second light emitting layer EML2 to the first luminous efficiency of the first light emitting layer EML1, the luminous efficiency of the entire light emitting element layer including the first light emitting layer EML1 and the second light emitting layer EML2 may be adjusted.

In an embodiment, the thickness of the second emitting layer EML2 may be about 50 angstroms to about 200 angstroms greater than the thickness of the first emitting layer EML1 When the thickness of the second light emitting layer EML2 is formed to be about 50 angstroms to about 200 angstroms greater than the thickness of the first light emitting layer EML1, the second luminous efficiency may be higher than the first luminous efficiency. Accordingly, the luminous efficiency of the light emitting element layer can be effectively improved.

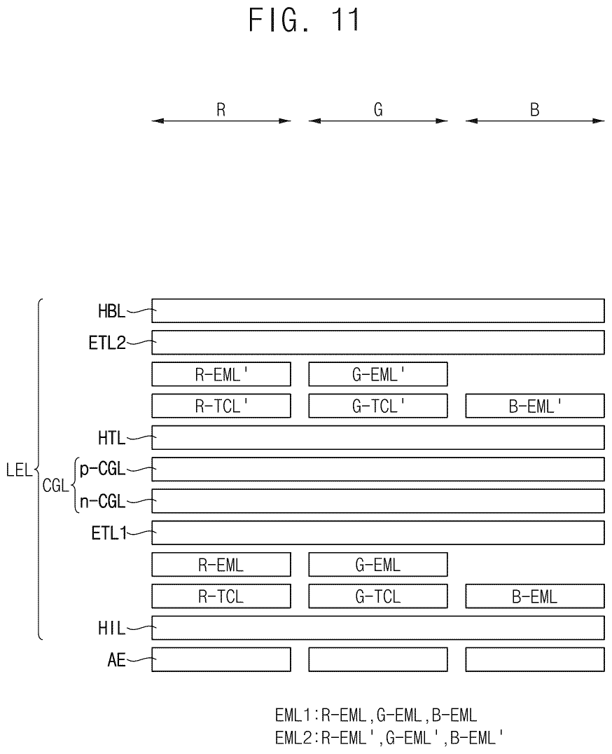

Referring further to FIG. 11, the second electron transport layer ETL2 may be formed on the second light emitting layer EML2. In an embodiment, the second luminous efficiency of the second light emitting layer EML2 may be adjusted by adjusting the thickness of the second electron transport layer ETL2.

The hole blocking layer HBL may be formed on the second electron transport layer ETL2. Accordingly, the light emitting element layer LEL including the hole injection layer HIL, the first light emitting layer EML1, the first electron transport layer ETL1, the charge generation layer CGL, the hole transport layer HTL, the second light emitting layer EML2, the second electron transport layer ETL2, and the hole blocking layer HBL may be formed.

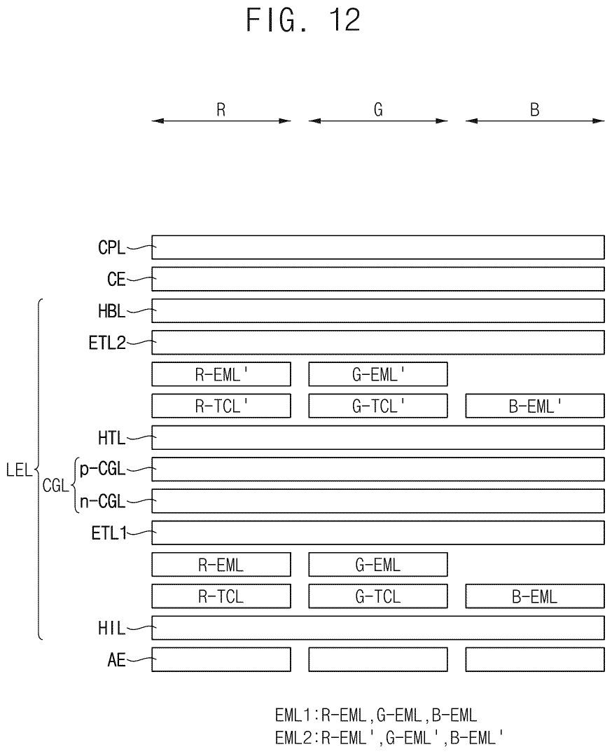

Referring further to FIG. 12, the common electrode CE may be formed on the hole blocking layer HBL. In addition, the capping layer CPL may be formed on the common electrode CE.

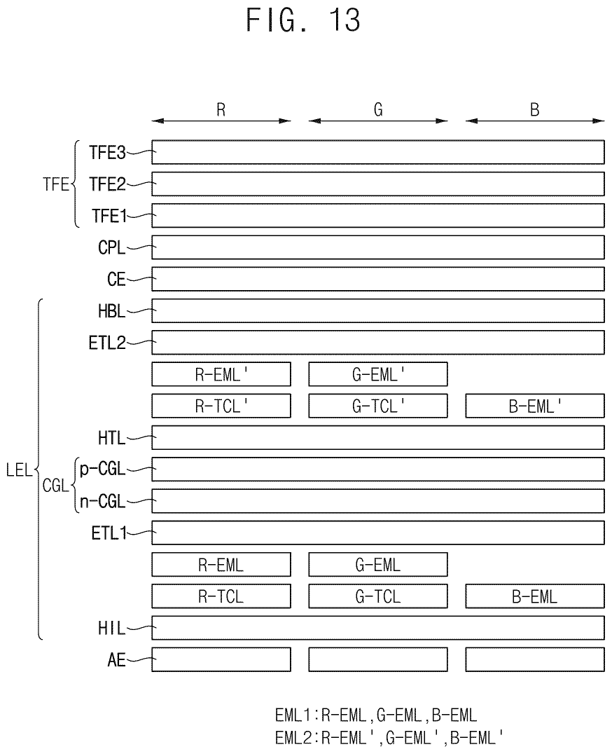

Referring further to FIG. 13, the encapsulation layer TFE may be formed on the common electrode CE. The encapsulation layer TFE may include the first, second, and third encapsulation layers TFE1, TFE2, and TFE3. Specifically, the first encapsulation layer TFE1 may be formed on the capping layer CPL and may be formed of silicon nitride. The second encapsulation layer TFE2 may be formed on the first encapsulation layer TFE1 and may be formed of silicon oxynitride. The third encapsulation layer TFE3 may be formed on the second encapsulation layer TFE2 and may be formed of silicon oxynitride.

In an embodiment, the luminous efficiency of the light emitting element layer LEL may be adjusted by adjusting the refractive index of each of the first, second, and third encapsulation layers TFE1, TFE2, and TFE3. For example, the refractive index of each of the first, second, and third encapsulation layers TFE1, TFE2, and TFE3 may be adjusted by adjusting the content ratio of elements included in each of the first, second, and third encapsulation layers TFE1, TFE2, and TFE3. In an embodiment, for example, the refractive index of the first encapsulation layer TFE1 may be adjusted by adjusting the content ratio of silicon and nitrogen in the silicon nitride included in the first encapsulation layer TFE1. The refractive index of the second encapsulation layer TFE2 may be adjusted by adjusting the content ratio of oxygen and nitrogen in the silicon oxynitride included in the second encapsulation layer TFE2. In addition, the refractive index of the third encapsulation layer TFE3 may be adjusted by adjusting the content ratio of oxygen and nitrogen in the silicon oxynitride included in the third encapsulation layer TFE3.

In an embodiment, the luminous efficiency of the light emitting element layer LEL may be adjusted by adjusting the thickness of each of the first, second, and third encapsulation layers TFE1, TFE2, and TFE3. In an embodiment, for example, the thickness of the first encapsulation layer TFE1 may range from about 1000 angstroms to about 1600 angstroms. The thickness of the second encapsulation layer TFE2 may range from about 6000 angstroms to about 12000 angstroms. The thickness of the third encapsulation layer TFE3 may range from about 50 angstroms to about 100 angstroms. However, the present disclosure is not limited to this.

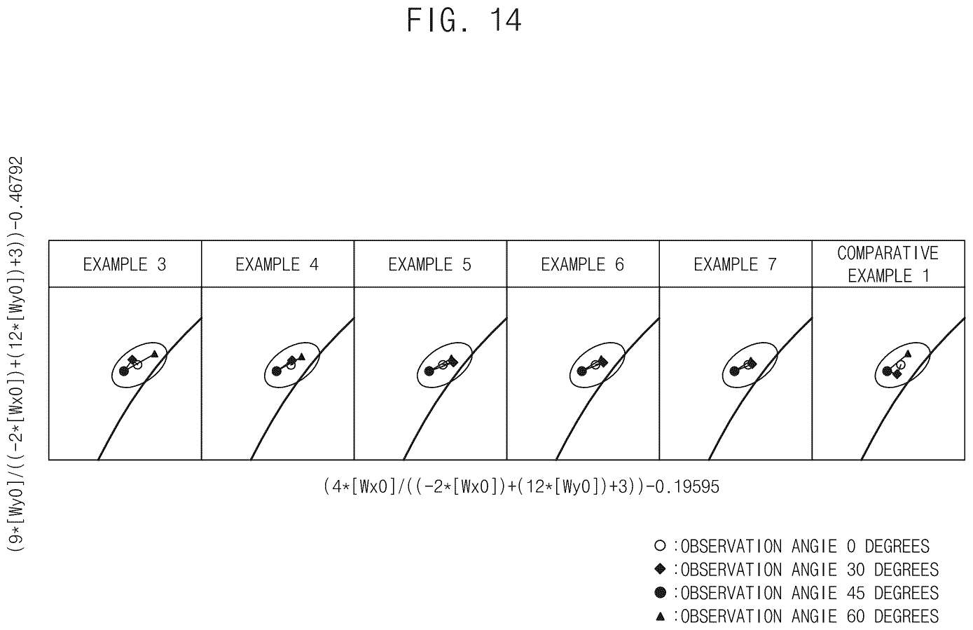

Hereinafter, the effects of the present disclosure will be further described with further reference to Table 3 and FIG. 14.

### Comparative Example 1, Example 3, Example 4, Example 5, Example 6, and Example 7

Under the condition that the ratio of the first luminous efficiency to the second luminous efficiency of the light emitting element layer according to each of Examples is 1:3, the thicknesses of the first encapsulation layer and the second encapsulation layer according to each of Comparative Examples and Examples are shown in Table 3 below. At this time, the refractive index of the first encapsulation layer is about 1.89, and the refractive index of the second encapsulation layer is about 1.62.

TABLE 3

| | Thickness | Thickness | | | | | |
|---|---|---|---|---|---|---|---|
| | of the first | of the second | | | Hole | Red | Green |
| | encapsulation | encapsulation | | | transport | thickness | thickness |
| | layer | layer | | Luminance | layer | compensation | compensation |
| | (angstroms) | (angstroms) | Δ Weff | ratio | margin | layer margin | layer margin |
| Comparative | 1300 | 9000 | 0.0% | 0.39 | 0% | 0% | 0% |
| Example 1 | | | | | | | |
| Example 3 | 1300 | 9000 | 2.6% | 0.45 | 21% | 4% | 0% |
| Example 4 | 1350 | 9000 | 2.7% | 0.45 | 28% | 3% | 4% |
| Example 5 | 1400 | 8700 | 2.9% | 0.45 | 28% | 4% | 10% |
| Example 6 | 1400 | 9000 | 2.9% | 0.45 | 29% | 4% | 10% |
| Example 7 | 1400 | 9300 | 2.9% | 0.44 | 28% | 5% | 11% |

FIG. 14 is graphs illustrating WAD characteristics in Comparative Example and Examples.

In FIG. 14, Wx0 means an initial color coordinate of the x-axis, and Wy0 means an initial color coordinate of the y-axis.

Referring to Table 3 and FIG. 14, under the above conditions, in Comparative Examples and Examples, WAD characteristics, white efficiency increase ratio (ΔWeff), luminance ratio, hole injection layer margin, red thickness compensation layer margin, and green thickness compensation layer margin were measured.

That the WAD characteristics, white efficiency increase ratio, luminance ratio, hole injection layer margin, red thickness compensation layer margin, and green thickness compensation layer margin of the light emitting element layer according to each of Examples are improved compared to Comparative Example can be confirmed

In addition, as the thickness of the first encapsulation layer and the thickness of the second encapsulation layer are changed in Examples, the white efficiency increase ratio of the light emitting element layer, the hole injection layer margin, the red thickness compensation layer margin, and the green thickness compensation layer margin are changed can be confirmed. Among Examples, that the white efficiency increase ratio, the hole injection layer margin, the red thickness compensation layer margin, and the green thickness compensation layer margin of the light emitting element layer according to Example 7 are most improved compared to Comparative Example can be confirmed. In addition, that all WAD trajectories according to Examples are arranged within the WAD specifications. In addition, that the movement amount of the WAD trajectory according to Example 7 is the smallest can be confirmed.

In an embodiment, as the light emitting element layer LEL is formed so that the second luminous efficiency is greater than the first luminous efficiency, the luminous efficiency and luminance ratio of the display device 10 can be effectively improved. In addition, the white angle difference (WAD) margin of the display device 10 can be increased. Accordingly, when the WAD margin is increased, the same WAD characteristics can be obtained even when the dispersion of the film thickness increases. Accordingly, the reliability of the display device 10 can be effectively improved.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a substrate;
a pixel electrode disposed on the substrate;
a light emitting element layer including a first light emitting layer disposed on the pixel electrode and having a first luminous efficiency and a second light emitting layer disposed on the first light emitting layer and having a second luminous efficiency higher than the first luminous efficiency; and
a common electrode disposed on the light emitting element layer.

2. The display device of claim 1, wherein the second luminous efficiency is about three times the first luminous efficiency.

3. The display device of claim 1, wherein the second light emitting layer has a thickness greater than a thickness of the first light emitting layer.

4. The display device of claim 3, wherein the thickness of the second light emitting layer is about 50 angstroms to about 200 angstroms greater than the thickness of the first light emitting layer.

5. The display device of claim 1, wherein the light emitting element layer further includes:
a first electron transport layer disposed between the first light emitting layer and the second light emitting layer;
a hole transport layer disposed between the first electron transport layer and the second light emitting layer; and
a second electron transport layer disposed between the second light emitting layer and the common electrode.

6. The display device of claim 1, further comprising:
an encapsulation layer disposed on the common electrode.

7. The display device of claim 6, wherein the encapsulation layer includes:
a first encapsulation layer including silicon nitride;
a second encapsulation layer disposed on the first encapsulation layer and including silicon oxynitride; and
a third encapsulation layer disposed on the second encapsulation layer and including silicon oxynitride.

8. The display device of claim 7, wherein a refractive index of the first encapsulation layer is greater than each of a refractive index of the second encapsulation layer and a refractive index of the third encapsulation layer, and
the refractive index of the second encapsulation layer is greater than the refractive index of the third encapsulation layer.

9. The display device of claim 7, wherein a thickness of the first encapsulation layer ranges from about 1000 angstroms to about 1600 angstroms,
a thickness of the second encapsulation layer ranges from about 6000 angstroms to about 12000 angstroms, and
a thickness of the third encapsulation layer ranges from about 50 angstroms to about 100 angstroms.

10. The display device of claim 1, wherein the light emitting element layer further includes:
a charge generating layer disposed between the first light emitting layer and the second light emitting layer.

11. A method of manufacturing a display device, the method comprising:
forming a pixel electrode on a substrate;
forming a first light emitting layer having a first luminous efficiency on the pixel electrode;
forming a second light emitting layer having a second luminous efficiency higher than the first luminous efficiency on the first light emitting layer; and
forming a common electrode on the second light emitting layer.

12. The method of claim 11, wherein the first light emitting layer and the second light emitting layer form a light emitting element layer.

13. The method of claim 12, wherein a luminous efficiency of the light emitting element layer is adjusted by adjusting a thickness of the second light emitting layer with respect to a thickness of the first light emitting layer.

14. The method of claim 13, wherein the thickness of the second light emitting layer is greater than the thickness of the first light emitting layer.

15. The method of claim 14, wherein the thickness of the second light emitting layer is about 50 angstroms to about 200 angstroms greater than the thickness of the first light emitting layer.

16. The method of claim 12, further comprising:
forming a hole injection layer on the pixel electrode before the forming of the first light emitting layer;
forming a hole transport layer on the first light emitting layer; and
forming an electron transport layer on the second light emitting layer after the forming of the second light emitting layer.

17. The method of claim 16, wherein a luminous efficiency of the light emitting element layer is adjusted by adjusting a thickness of each of the hoe injection layer, the hole transport layer, and the electron transport layer.

18. The method of claim 12, further comprising:
forming a first encapsulation layer including silicon nitride on the common electrode;
forming a second encapsulation layer including silicon oxynitride on the first encapsulation layer; and
forming a third encapsulation layer including silicon oxynitride on the second encapsulation layer.

19. The method of claim 18, wherein a refractive index of each of the first, second, and third encapsulation layers is adjusted by adjusting a content ratio of elements included in each of the first, second, and third encapsulation layers.

20. The method of claim 18, wherein a luminous efficiency of the light emitting element layer is adjusted by adjusting a thickness of each of the first, second, and third encapsulation layers.
